(19) United States
(12) Patent Application Publication
(10) Pub. No.: US 2025/0201757 A1
(43) Pub. Date: Jun. 19, 2025

(54) CHIP BONDING APPARATUS

(71) Applicant: Samsung Electronics Co., Ltd., Suwon-si (KR)

(72) Inventors: Taejae PARK, Suwon-si (KR); Gongmyeong KIM, Suwon-si (KR); Sunchul KIM, Suwon-si (KR); Chaein MOON, Suwon-si (KR); Hyeonrae CHO, Suwon-si (KR)

(73) Assignee: Samsung Electronics Co., Ltd., Suwon-si (KR)

(21) Appl. No.: 18/975,132

(22) Filed: Dec. 10, 2024

(30) Foreign Application Priority Data
Dec. 19, 2023 (KR) 10-2023-0186300

(51) Int. Cl. H01L 23/00

(52) U.S. Cl. CPC H01L 24/75; H01L 2224/75263; H01L 2224/75753; H01L 2224/75983; H01L 2924/401

(57) ABSTRACT

A chip bonding apparatus includes a stage configured to support a plurality of substrates, a bonding head located to face an upper surface of the stage in a vertical direction and configured to hold a plurality of semiconductor chips and transmit a laser beam, and a laser irradiating unit configured to irradiate a laser beam toward the semiconductor chips, wherein a plurality of trenches are formed in a lower surface of the bonding head.

### CROSS-REFERENCE TO RELATED APPLICATION

This application is based on and claims priority under 35 U.S.C. § 119 to Korean Patent Application No. 10-2023-0186300, filed on Dec. 19, 2023, in the Korean Intellectual Property Office, the disclosure of which is incorporated by reference herein in its entirety.

### BACKGROUND

Inventive concepts relate to a chip bonding apparatus, for example to a chip bonding apparatus for simultaneously bonding a plurality of chips to a substrate.

A chip bonding process for bonding a substrate and one or more semiconductor chips to each other may be performed by using various bonding apparatuses such as, for example, a thermal compression (TC) bonding apparatus and a laser bonding apparatus. A laser bonding apparatus may, for example, generate heat in a semiconductor chip by irradiating a laser beam to the semiconductor chip, which may be mounted on a substrate. The generated heat may be transmitted to a pad on the substrate and a solder bump of the semiconductor chip and thus the solder bump may be bonded to the pad. Unlike other methods of bonding a semiconductor chip to a substrate by applying heat thereto, the laser bonding apparatus may, for example, transmit heat only to a semiconductor chip by irradiating a laser beam thereto. Also, the laser bonding apparatus may bond a semiconductor chip to a substrate by applying pressure to the substrate and the semiconductor chip through a bonding head including, for example, quartz.

### SUMMARY

Inventive concepts relate to a chip bonding apparatus with improved bonding efficiency.

Also, the problems to be solved by inventive concepts are not limited to the above problems, and other problems may be clearly understood by those of ordinary skill in the art from the following description.

In order to achieve the technical goals, inventive concepts relate to the following chip bonding apparatus.

According to aspects of inventive concepts, there is provided a chip bonding apparatus including a stage configured to support a plurality of substrates, a bonding head located to face an upper surface of the stage in a vertical direction and configured to hold a plurality of semiconductor chips and transmit a laser beam, and a laser irradiating unit configured to irradiate a laser beam toward the semiconductor chips, wherein a plurality of trenches are at least partially defined by in a lower surface of the bonding head.

According to aspects of inventive concepts, there is provided a chip bonding apparatus including a stage configured to support a plurality of substrates, a bonding head located to face an upper surface of the stage in a vertical direction and configured to hold a plurality of semiconductor chips, transmit a laser beam, and ascend and descend in the vertical direction, and a laser irradiating unit configured to irradiate a laser beam toward the semiconductor chips, wherein a plurality of trenches are at least partially defined by in a lower surface of the bonding head, a footprint of the bonding head is greater than or equal to a sum of respective footprints of the plurality of semiconductor chips, and a footprint of the stage is greater than or equal to a sum of respective footprints of the plurality of substrates.

According to aspects of inventive concept, there is provided a chip bonding apparatus including a stage configured to support a plurality of substrates, a bonding head located to face an upper surface of the stage in a vertical direction and including a transmission unit configured to hold a plurality of semiconductor chips and transmit a laser beam, a support unit surrounding a sidewall of the transmission unit, and a connection unit connected to the support unit, a camera configured to measure an alignment state of the semiconductor chip and the substrate, and a laser irradiating unit configured to irradiate a laser beam toward the semiconductor chips, wherein a plurality of trenches are at least partially defined by in a lower surface of the transmission unit, a footprint of the transmission unit is greater than or equal to a sum of respective footprints of the plurality of semiconductor chips, a footprint of the stage is greater than or equal to a sum of respective footprints of the plurality of substrates, and a hole penetrating from an upper surface of the transmission unit to a bottom surface of the trench is formed in the transmission unit.

### BRIEF DESCRIPTION OF THE DRAWINGS

Example embodiments will be more clearly understood from the following detailed description taken in conjunction with the accompanying drawings in which:

FIG. 1 is a block diagram schematically illustrating a chip bonding system according to embodiments;

FIGS. 2 to 6 are cross-sectional views for describing a chip bonding apparatus according to some example embodiments;

FIG. 7 is a plan view illustrating a chip bonding apparatus according to some example embodiments;

FIG. 8 is a cross-sectional view illustrating a chip bonding apparatus according to some example embodiments;

FIG. 9 is a cross-sectional view illustrating a chip bonding apparatus according to some example embodiments;

FIG. 10 is a cross-sectional view illustrating a chip bonding apparatus according to some example embodiments; and

FIG. 11 is a cross-sectional view illustrating a chip bonding apparatus according to some example embodiments.

### DETAILED DESCRIPTION

Hereinafter, some example embodiments will be described in more detail with reference to the accompanying drawings. Herein, like reference numerals will denote like elements, and redundant descriptions thereof will be omitted for conciseness.

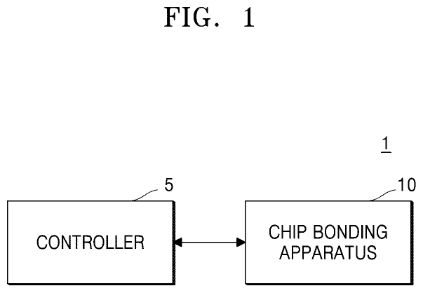

FIG. 1 is a block diagram schematically illustrating a chip bonding system according to some example embodiments.

Referring to FIG. 1, a chip bonding system 1 may include a controller 5 and a chip bonding apparatus 10. The chip bonding system 1 may be used in, for example, a semiconductor package manufacturing process. For example, the chip bonding system 1 may be configured to bond a semiconductor chip and a substrate, included in a semiconductor package, to each other. According to some example embodiments, the chip bonding system 1 may bond a semiconductor chip and a semiconductor substrate to each other by irradiating a laser beam to the semiconductor chip. However, example embodiments are not limited thereto.

The controller 5 may be configured to control the chip bonding apparatus 10. For example, the controller 5 may control the chip bonding apparatus 10 to switch between a turn-on state and a turn-off state. When the controller 5 turns on the chip bonding apparatus 10 (for example, when the chip bonding apparatus is switched to a turn-on state), a chip bonding process by the chip bonding apparatus 10 may be performed. When the controller 5 turns off the chip bonding apparatus 10 (for example when the chip bonding apparatus is switched to a turn-off state), the chip bonding process by the chip bonding apparatus 10 may be stopped. The controller 5 may be implemented as, for example, hardware, firmware, software, or any combination thereof. For example, the controller 5 may include a computing device such as a workstation computer, a desktop computer, a laptop computer, or a tablet computer. The controller 5 may include, for example, a simple controller, a complex processor such as a microprocessor, a central processing unit (CPU), or a graphic processing unit (GPU), a processor including software, and/or dedicated hardware or firmware, but example embodiments are not limited thereto. The controller 5 may be implemented by, for example, a general-purpose computer or application-specific hardware such as a digital signal processor (DSP), a field programmable gate array (FPGA), and an application-specific Integrated Circuit (ASIC), but example embodiments are not limited thereto. The controller 5 may be implemented as, for example, instructions stored on a machine-readable medium that may be read and executed by one or more processors. Here, the machine-readable medium may include, for example, any mechanism for storing and/or transmitting information in a form readable by a machine (e.g., a computing device). For example, the machine-readable medium may include, for example, a read only memory (ROM), a random access memory (RAM), a magnetic disk storage medium, an optical storage medium, a flash memory device, electrical, optical, acoustic, or other types of radio signals (e.g., carrier waves, infrared signals, and digital signals), and other suitable signals, but example embodiments are not limited thereto.

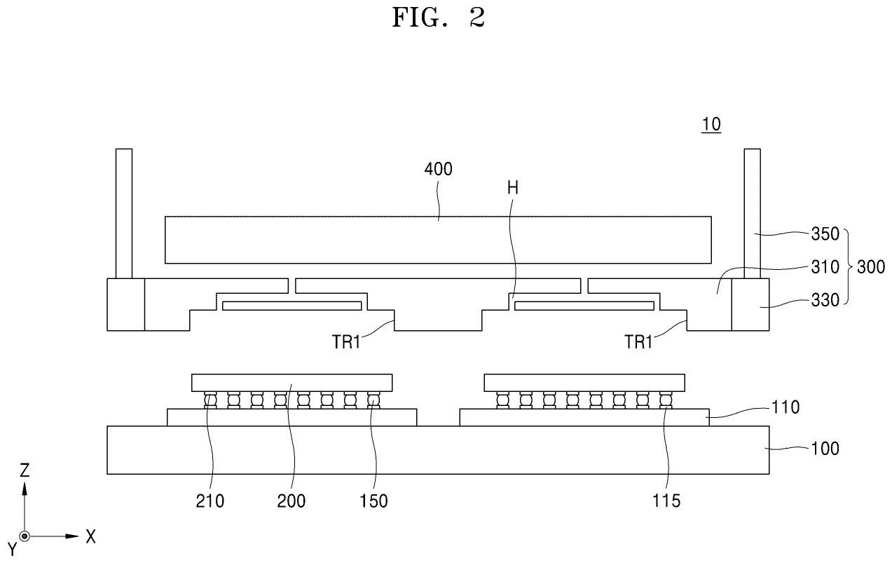

The chip bonding apparatus 10 may be configured to bond a chip and a semiconductor substrate to each other. According to some example embodiments, the chip bonding apparatus 10 may include, for example, a laser assisted bonding (LAB) facility and/or a laser compression bonding (LCB) facility, but example embodiments are not limited thereto. A detailed configuration of the chip bonding apparatus 10 will be described in detail with reference to FIG. 2.

The chip bonding apparatus 10 may, for example, provide various information to the controller 5. For example, the chip bonding apparatus 10 may provide the controller 5 with a result or results of monitoring the chip bonding apparatus 10 and a product (or products) to be bonded. The controller 5 may, for example, analyze a result or results of said monitoring and/or control the chip bonding apparatus 10 accordingly.

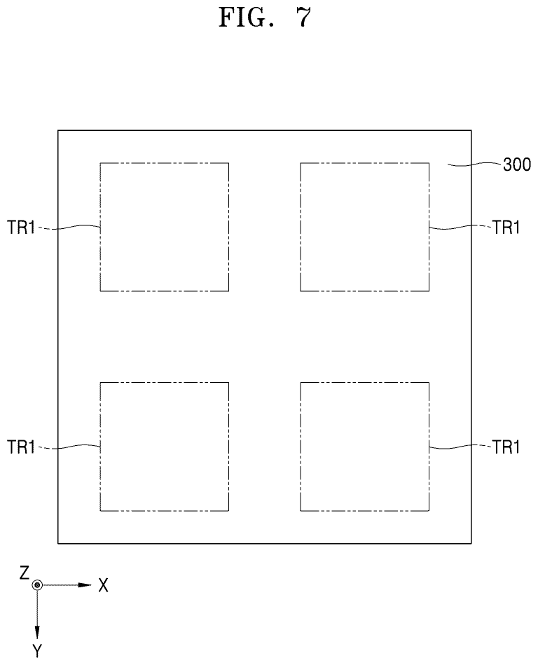

FIGS. 2 to 6 are cross-sectional views for describing a chip bonding apparatus 10 according to some example embodiments. FIG. 7 is a plan view illustrating a chip bonding apparatus according to some example embodiments.

Referring to FIGS. 2 to 7, the chip bonding apparatus 10 may include a stage 100, a bonding head 300, and a laser irradiating unit 400. The stage 100 may be configured to support a substrate 110. In some example embodiments, the stage 100 may be additionally or alternatively configured to support a semiconductor chip 200. According to some example embodiments, the upper surface of the stage 100 may have a flat or substantially flat shape, but example embodiments are not limited thereto.

In the following drawings, an X-axis direction and a Y-axis direction may be parallel to the upper surface of the stage 100, and the X-axis direction and Y-axis direction may be perpendicular to each other. A Z-axis direction may be perpendicular to the upper surface of the stage 100. In other words, the Z-axis direction may be perpendicular to an X-Y plane.

Also, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

First, referring to FIG. 2, a substrate 110, a substrate pad 115, a bump 150, a semiconductor chip pad 210, and a semiconductor chip 200 as illustrated in FIG. 2 may be understood as being in a state in which the substrate 110, the substrate pad 115, the bump 150, the semiconductor chip pad 210, and the semiconductor chip 200 are initially provided to the chip bonding apparatus 10 from the outside.

The substrate 110 may be arranged on the stage 100. The lower surface of the substrate 110 may or may not physically contact the upper surface of the stage 100. The substrate(s) 110 may include, for example, at least one of a ceramic substrate, a printed circuit board (PCB), and/or an organic substrate, but example embodiments are not limited thereto. The substrate 110 may be provided as a plurality of substrates 110 on the upper surface of the stage 100. Individual substrates of plurality of substrates 110 may be provided apart from each other in the horizontal direction X and Y. The footprint of the stage 100 may be equal to, substantially equal to, or greater than the sum of the respective footprints of the plurality of substrates 110.

The substrate pads 115 may be provided on the upper surface of the substrate 110. The substrate pads 115 may be provided in a state of being coupled to the substrate 110. The substrate pads 115 may include one or more conductive materials. For example, any or all of the substrate pads 115 may include one or more conductive materials, such as for example, copper (Cu), aluminum (Al), silver (Ag), tin (Sn), gold (Au), nickel (Ni), lead (Pb), titanium (Ti), or any alloy thereof, but example embodiments are not limited thereto. The substrate pads 115 may be electrically connected to one or more conductive materials formed in or on the substrate 110. However, example embodiments are not limited thereto.

The semiconductor chip 200 may be arranged over or on the substrate 110. The semiconductor chip 200 may also be provided as a plurality of semiconductor chips 200. Accordingly, the semiconductor chips 200 may be arranged, for example respectively arranged, over the plurality of substrates 110. The semiconductor chip 200 may include, for example, at least one of a memory chip and a logic chip. The memory chip may include, for example, at least one of a volatile memory chip such as a dynamic random access memory (DRAM) chip or a static random access memory (SRAM) chip and/or may include, for example, at least one of a nonvolatile memory chip such as a phase-change random access memory (PRAM) chip, a magnetoresistive random access memory (MRAM) chip, a ferroelectric random access memory (FeRAM) chip, or a resistive random access memory (RRAM) chip, and the logic chip may include, for example, at least one of a microprocessor such as a central processing unit (CPU), a graphic processing unit (GPU), or an application processor (AP), an analog device, or a digital signal processor, but example embodiments are not limited thereto.

The semiconductor chip pads 210 may be provided on lower surface(s) of the semiconductor chip(s) 200. The semiconductor chip pads 210 may individually include at least one conductive material. The bumps 150 may be provided on the lower surface of any or each of the semiconductor chip pads 210. The bumps 150 may individually include, for example, a pillar structure, a ball structure, and/or a solder layer.

According to some example embodiments, the semiconductor chip 200, the semiconductor chip pad 210, and the bump 150 may be integrally provided as one body. For example, the semiconductor chip 200, semiconductor chip pads 210, and bump 150 may be provided in a combined state. For example, the semiconductor chip pad 210 may be provided in a state of being coupled onto the lower surface of the semiconductor chip 200, and the bump 150 may be provided in a state of being coupled onto the lower surface of the semiconductor chip pad 210.

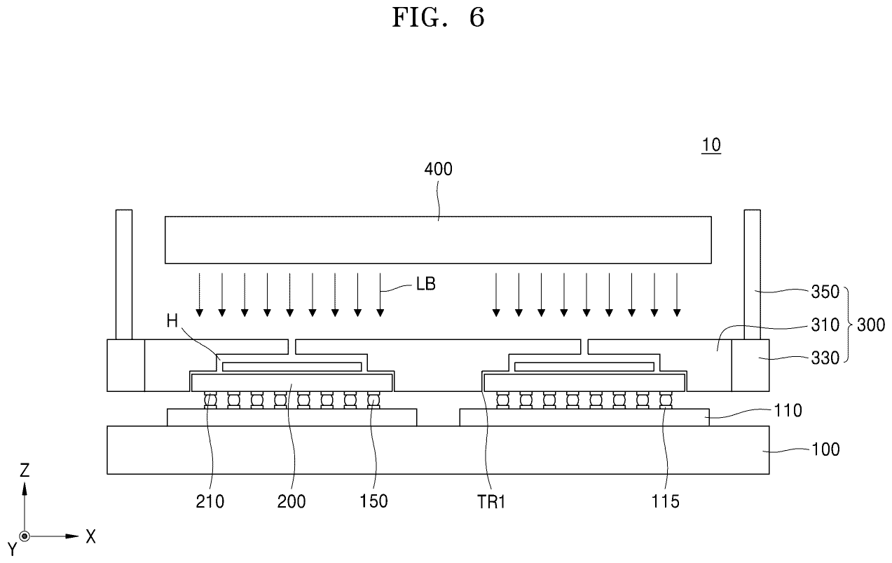

The semiconductor chip 200, the semiconductor chip pad 210, and the bump 150, when integrally provided, for example, as one body, may be located on the upper surface of the substrate pads 115. According to some example embodiments, in such a case, the bump 150 may be provided on the upper surface of the substrate pad 115 in a state of not being coupled to the substrate pad 115. For example, the bump 150 may be provided in a state of being coupled only to the semiconductor chip pad 210 and may be provided in a state of not being coupled to the substrate pad 115. However, as described below, in some example embodiments the bump 150 and the substrate pad 115 may be bonded to each other through the transmission of heat by a laser beam LB illustrated in FIG. 6 and/or pressing of the upper surface of the semiconductor chip 200 by the bonding head 300.

The bonding head 300 may be located over the semiconductor chip 200. The semiconductor chip 200 and the bonding head 300 may be located apart from each other in the vertical direction Z. The bonding head 300 may include, for example, a transmission unit 310, a support unit 330, and a connection unit 350. The transmission unit 310 may be configured to transmit the laser beam LB irradiated by the laser irradiating unit 400 as illustrated in FIG. 6. The transmission unit 310 may include, for example, a transparent material, but example embodiments are not limited thereto. For example, the transmission unit 310 may include, for example, quartz, but example embodiments are not limited thereto. Also, the transmission unit 310 may be configured to press the upper surface of the semiconductor chip 200. For example, the transmission unit 310 may be configured to descend in the vertical direction Z to apply pressure to the upper surface of the semiconductor chip 200. The footprint of the transmission unit 310 may be greater than the sum of the respective footprints of the plurality of semiconductor chips 200 provided over the stage 100. Each of the plurality of semiconductor chips 200 may overlap with (for example, be covered or at least partially covered by) the transmission unit 310 in the vertical direction Z. For example, the entire upper surface of each of the plurality of semiconductor chips 200 may overlap with the transmission unit 310 in the vertical direction Z, but example embodiments are not limited thereto.

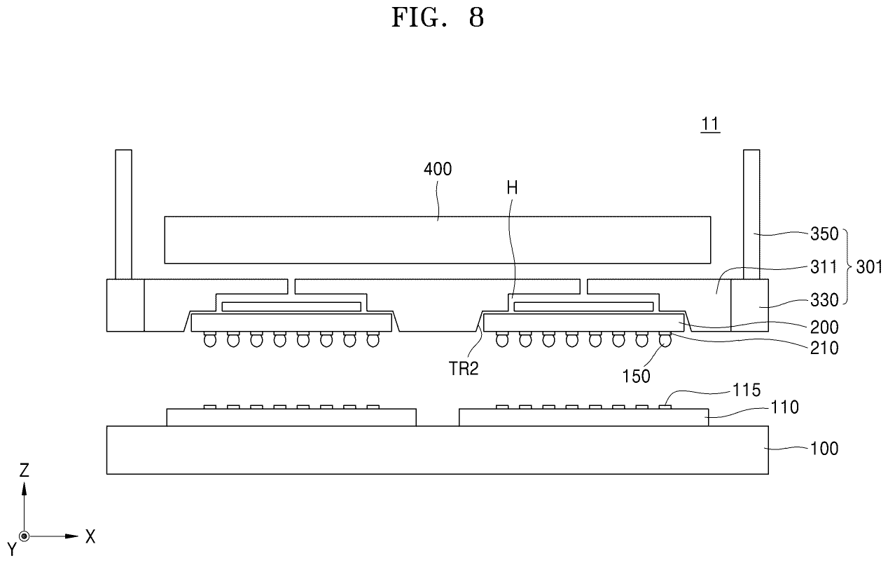

A trench TR1 may be formed in (for example, defined or least partially defined by) the lower surface of the transmission unit 310. According to some example embodiments, the trench TR1 may have a shape extending upwards from a vertical level of one portion of the lower surface of the transmission unit 310, defining an opening or upper boundary of the trench TR1, towards another portion of the lower surface, defining a bottom surface (for example, base) of the transmission unit 310, in the vertical direction Z. Restated, the trench TR1 may be vertically defined between portions of the lower surface of the transmission unit that are located at different vertical levels, and horizontally defined between opposing inner side walls of the transmission unit vertically connecting said portions of the of the lower surface of the transmission unit 310. In such a case, said inner sidewalls of the transmission unit 310, which may be understood to respectively define sidewalls of the trench TR1, may be formed to be perpendicular to the lower surface of the transmission unit 310. In other words, the sidewall of the trench TR1 may be perpendicular to the bottom surface (for example, base) of the trench TR1. According to some example embodiments, the footprint of the trench TR1 may be equal or substantially equal to the footprint of the semiconductor chip 200. Also, the depth of the trench TR1 (defined by, for example, by a vertical distance between portions of the lower surface of the transmission unite 310 vertically defining the trench TR1) in the vertical direction Z may be equal or substantially equal to the height of the semiconductor chip 200 in the vertical direction Z. However, the shape, footprint, and depth of the trench TR1 are not limited thereto, and the shape, footprint, and depth of the trench TR1 may be variously provided as illustrated in, for example, FIGS. 8 to 11, but example embodiments are not limited thereto.

The trench TR1 may be provided as a plurality of trenches TR1. For example, four trenches TR1 may be provided in (for example, defined or at least partially by) the lower surface of the transmission unit 310 as illustrated in FIG. 7. However, the number of trenches TR1 is not limited thereto, and for example, two, three, or five or more trenches TR1 may be provided. Also, FIG. 7 illustrates that four trenches TR1 are provided in two rows and two columns; however, the arrangement of the trenches TR1 is not limited thereto, and the trenches TR1 may be provided in various arrangements such as, for example, being arranged in a straight line.

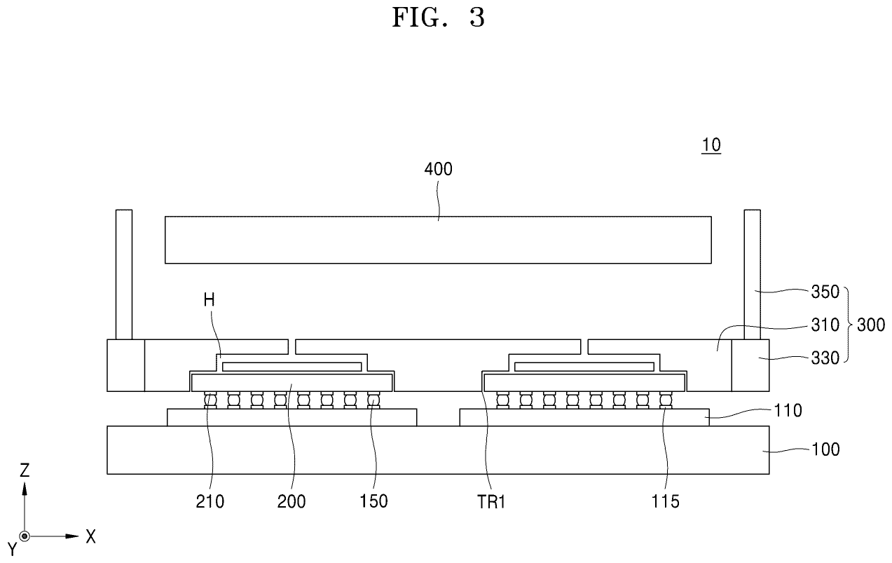

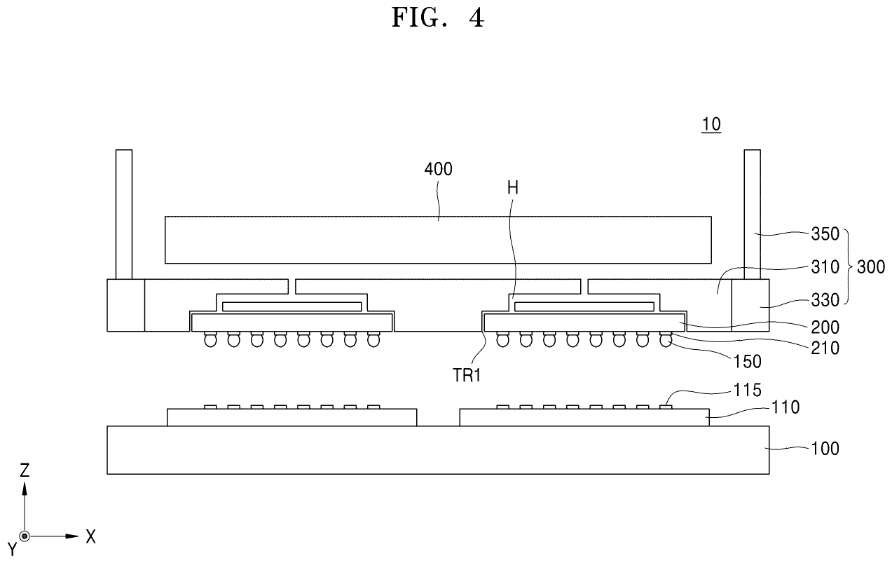

According to some example embodiments, a hole H may be formed in (for example, defined by) the transmission unit 310. The hole H may be formed to penetrate the transmission unit 310 from the upper surface of the transmission unit 310 to the trench TR1. In other words, the hole H may be defined to extend from the upper surface of the transmission unit 310 to the trench TR1. According to some example embodiments, the hole H may be or include a path through which gas passes. A compressor (not illustrated) may be provided on the upper surface of the transmission unit 310 may be configured to suction gas through (for example, via) the hole H. Accordingly, as illustrated in FIGS. 3 and 4, the bonding head 300 may press and lift up the semiconductor chip 200, the semiconductor chip pad 210, and the bump 150 in the vertical direction Z.

The support unit 330 may surround the sidewalls of the transmission unit 310. For example, the support unit 330 may support the transmission unit 310 by being connected to the sidewall of the transmission unit 310. Also, by being connected to the sidewall of the transmission unit 310, the support unit 330 may fix or stabilize the transmission unit 310 such that it does not shake or substantially shake in the horizontal directions X and Y. According to some example embodiments, the support unit 330 may not include a transparent material but may include an opaque material, but example embodiments are not limited thereto. Accordingly, in such a case the laser beam LB emitted from the laser irradiating unit 400 may not pass through the support unit 330. For example, the laser beam LB emitted from the laser irradiating unit 400 may only pass through the transmission unit 310, but example embodiments are not limited thereto.

The connection unit 350 may be configured to connect an elevator (not illustrated) and the support unit 330 to each other. The elevator may be configured to drive the connection unit 350 in the vertical direction Z. For example, the elevator may be configured to raise or lower the connection unit 350 in the vertical direction Z. Because the connection unit 350 may be driven in the vertical direction Z by the elevator, the support unit 330 connected to the connection unit 350 and the transmission unit 310 connected to the support unit 330 may also be driven in the vertical direction Z. The transmission unit 310 may be lowered in the vertical direction Z by the connection unit 350 and the support unit 330, and accordingly, the transmission unit 310 may simultaneously press each of the plurality of semiconductor chips 200. Also, the transmission unit 310 may be raised in the vertical direction Z by the connection unit 350 and the support unit 330, and each of the plurality of semiconductor chips 200 may be moved upward in the vertical direction Z by adsorption of the plurality of semiconductor chips 200 through (for example, by using) the hole H formed in the transmission unit 310. In such a case, each of the plurality of semiconductor chips 200 may be moved upward in the vertical direction Z together with the semiconductor chip pad 210 and the bumps 150 coupled to the lower surface of each of the plurality of semiconductor chips 200.

The laser irradiating unit 400 may be provided over the bonding head 300. According to example embodiments, the laser irradiating unit 400 may be provided integrally with the bonding head 300 or may be provided separately from the bonding head 300. The laser irradiating unit 400 may be arranged to overlap with each of the plurality of semiconductor chips 200 in the vertical direction Z. Also, the laser irradiating unit 400 may be arranged to overlap the plurality of trenches TR1 formed in the transmission unit 310 in the vertical direction Z.

The laser irradiating unit 400 may irradiate a laser beam LB to a particular area. For example, the area of the laser beam LB irradiated by the laser irradiating unit 400 may be equal or substantially equal to the sum of the areas of the respective upper surfaces of the plurality of semiconductor chips 200. According to some example embodiments, only the upper surface of each of the plurality of semiconductor chips 200 may be irradiated by the laser beam LB, and an area on the upper surface of each of the plurality of substrates 110 not covered by the semiconductor chip 200 may not be irradiated by the laser beam LB.

FIGS. 3 and 4 together may be understood as illustrating a state in which the semiconductor chip 200, the semiconductor chip pad 210, and the bump 150 are separated from the substrate 110 by the bonding head 300 and ascend in the vertical direction Z.

The bonding head 300 initially spaced upwardly apart from the upper surface of the semiconductor chip 200 in the vertical direction Z may descend in the vertical direction Z due to the descent of the connection unit 350. As illustrated in FIG. 3, the bonding head 300 may be lowered in the vertical direction Z until the semiconductor chip 200 is seated in the trench TR1 defined by the transmission unit 310. Accordingly, the upper surface of the semiconductor chip 200 may contact (not shown) a lower surface of the transmission unit 310, but example embodiments are not limited thereto.

Thereafter, the upper surface of the semiconductor chip 200 may be vacuum-adsorbed through (for example, by using) the hole H formed in (for example defined by) the transmission unit 310 to couple the upper surface of the semiconductor chip 200 and the transmission unit 310 to each other. Accordingly, as illustrated in FIG. 4, the bonding head 300 may be raised in the vertical direction Z by the connection unit 350. Accordingly, the semiconductor chip 200, the semiconductor chip pad 210, and the bump 150 may ascend in the vertical direction Z. Consequently, semiconductor chip 200, the semiconductor chip pad 210, and the bump 150 may be spaced apart from the substrate 110 and the substrate pad 115 in the vertical direction Z. In such a case, the semiconductor chip 200 and the substrate 110 may be located to face each other in the vertical direction Z.

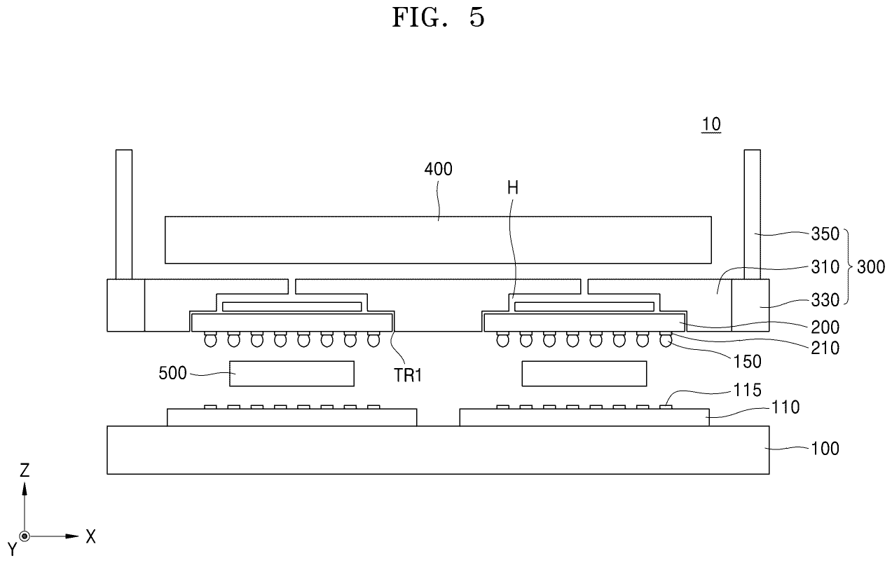

FIG. 5 may be understood as illustrating a state in which the positional relationship between the substrate 110 and the semiconductor chip 200 is measured through a camera 500 and the positions of the substrate 110 and the semiconductor chip 200 are aligned with each other.

The camera 500 may be provided between the substrate 110 and the semiconductor chip 200 to measure the positional relationship between the substrate 110 and the semiconductor chip 200. When the substrate 110 and the semiconductor chip 200 are determined to be being misaligned according to the positional relationship between the substrate 110 and the semiconductor chip 200 as measured by the camera 500, the stage 100 and/or the bonding head 300 may be moved to adjust the positional relationship between the substrate 110 and the semiconductor chip 200.

FIG. 6 may be understood as illustrating a state in which the bonding head 300 is lowered to press the upper surface of the semiconductor chip 200 downward in the vertical direction Z and a laser beam LB is irradiated to the semiconductor chip 200 to transmit heat between the bump 150 and the substrate pad 115.

As the upper surface of the semiconductor chip 200 is pressed by the bonding head 300, pressure in the vertical direction Z may be provided between the bump 150 and the substrate pad 115 (for example, from the bump 150 to the substrate pads 115). Also, heat may be transmitted between the bump 150 and the substrate pad 115 by using laser beam LB. The bump 150 and the substrate pad 115 may accordingly be bonded to each other by the pressure and/or heat transmission. As the bump 150 and the substrate pad 115 are bonded to each other, bonding of the semiconductor chip 200 and the substrate 110 may be completed.

In a chip bonding apparatus 10 according to some inventive concepts, a plurality of substrates 110 may be arranged on a stage 100, a semiconductor chip 200 may be arranged over the upper surface of each of the plurality of substrates 110, a bonding head 300 may simultaneously press each of the plurality of semiconductor chips 200, and a laser irradiating unit 400 may simultaneously irradiate a laser beam LB to each of the plurality of semiconductor chips 200.

In a related art, the footprint of a transmission unit 310 of a bonding head 300 is substantially equal to the footprint of a single semiconductor chip 200, and a laser irradiating unit 400 irradiates a laser beam LB to the single semiconductor chip 200. Accordingly, only one semiconductor chip 200 and one substrate 110 may be bonded to each other at a time through the pressing by the bonding head 300 and the provision of heat by the laser beam LB. However, compared to the time during which the laser beam LB is irradiated, more time is taken to press the upper surface of the semiconductor chip 200 by the bonding head 300, and thus, there may be an inefficiency in bonding the semiconductor chip 200 to the substrate 110.

However, the chip bonding apparatus 10 according to inventive concepts may simultaneously bond any or all plurality of semiconductor chips 200 to corresponding substrates of the plurality of substrates 110. Particularly, because the footprint of the transmission unit 310 is equal to, substantially equal to or greater than the sum of the footprints of the respective upper surfaces of the plurality of semiconductor chips 200 and the laser beam LB irradiated by the laser irradiating unit 400 is simultaneously irradiated to each of the plurality of semiconductor chips 200, the plurality of semiconductor chips 200 may be more efficiently bonded to the substrates 110.

Further, in the chip bonding apparatus 10 according to some inventive concepts, a plurality of trenches TR1 may be defined by the transmission unit 310, as discussed above. Accordingly, a semiconductor chip 200 may be arranged in each of the plurality of trenches TR1, and each semiconductor chip of the semiconductor chips 200 may be understood to respectively correspond a trench of the plurality of trenches TR1 in which it may be arranged. Because each of the plurality of semiconductor chips 200 may be seated in (for example, encapsulated or at least partially encapsulated by) a corresponding trench TR1, the stability of the semiconductor chips 200 during upward and downward driving thereof may be improved trenches TR1, and the alignment of the semiconductor chips 200 may be maintained without being misaligned or substantially misaligned.

FIG. 8 is a cross-sectional view illustrating a chip bonding apparatus according to some example embodiments. Hereinafter, redundant descriptions of a chip bonding apparatus 11 of FIG. 8 with those of the chip bonding apparatus 10 given above with reference to FIGS. 2 to 7 will be omitted and differences therebetween will be mainly described.

Referring to FIG. 8, the chip bonding apparatus 11 may include a stage 100, a bonding head 301, and a laser irradiating unit 400. The stage 100 may be configured to support a substrate 110. The bonding head 301 may be arranged apart from the upper surface of the stage 100 in the vertical direction Z. The bonding head 301 may be located to face the upper surface of the stage 100. The bonding head 301 may include a transmission unit 311, a support unit 330, and a connection unit 350.

A trench TR2 may be formed in the lower surface of the transmission unit 311. According to embodiments, the trench TR2 may be a shape extending from the lower surface of the transmission unit 311 upward in the vertical direction Z. The trench TR2 may be provided as a plurality of trenches TR2.

The footprint of the cross-section of the trench TR2 along the X-Y plane may decrease as the level in the vertical direction Z increases. In other words, the cross-section of the trench TR2 along the X-Z plane may have a tapered shape in which the horizontal width decreases as the vertical level increases. In other words, the horizontal distance between inner sidewalls of the transmission unit 310 defining sidewalls of the trench may decrease when moving upwards in the vertical direction Z. The sidewall of the trench TR2 may form an obtuse angle with respect to the bottom surface of the trench TR2.

Also, the distance from the side surface of the semiconductor chip 200 to the sidewall of the trench TR2 in the horizontal direction X may decrease as the footprint of the cross-section of the trench TR2 along the X-Y plane decreases as the level in the vertical direction Z increases.

A hole H may be formed in (for example, defined by) the transmission unit 311. For example, hole H may be formed (for example, defined) to penetrate (for example, extend through) the transmission unit 311 from the upper surface of the transmission unit 311 to the trench TR2. According to some embodiments, the hole H may be or include a path through which gas passes. The support unit 330 may surround the sidewall(s) (for example, the outer sidewall(s)) of the transmission unit 311. The connection unit 350 may be configured to connect an elevator (not illustrated) and the support unit 330 to each other. The elevator may be configured to drive the connection unit 350 in the vertical direction Z. The laser irradiating unit 400 may be provided over or on the bonding head 301. According to example embodiments, the laser irradiating unit 400 may be provided integrally with the bonding head 301 or may be provided separately from the bonding head 301.

In a case where the sidewall of the trench TR2 of the transmission unit 311 forms an obtuse angle with respect to the bottom surface of the trench TR2, when approaching the semiconductor chip 200 through the bonding head 301, even when the semiconductor chip 200 and the bonding head 301 are misaligned with each other, the sidewall of the trench TR2 formed in the bonding head 301 may apply a force in the horizontal direction X and Y to align the semiconductor chip 200 as the bonding head 301 descends.

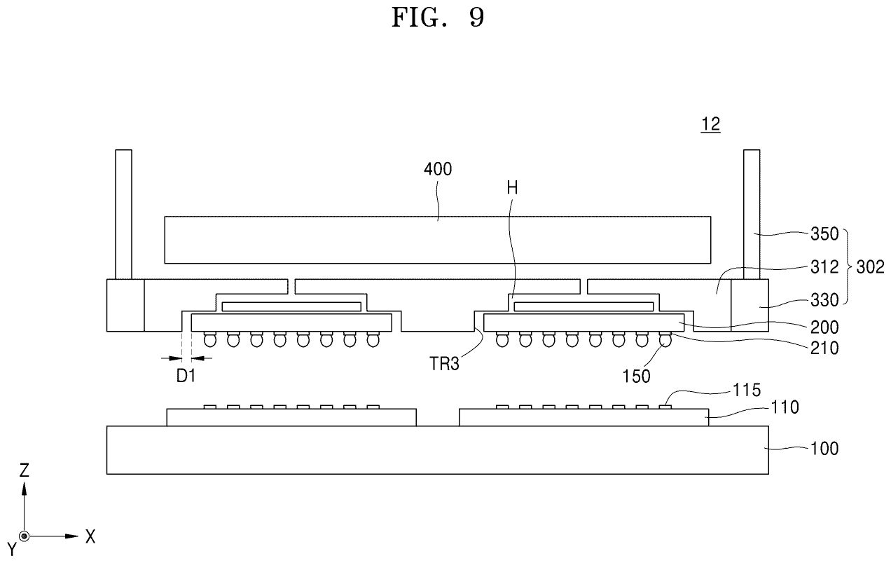

FIG. 9 is a cross-sectional view illustrating a chip bonding apparatus according to embodiments. Hereinafter, redundant descriptions of a chip bonding apparatus 12 of FIG. 9 with those of the chip bonding apparatus 10 given above with reference to FIGS. 2 to 7 will be omitted and differences therebetween will be mainly described.

Referring to FIG. 9, the chip bonding apparatus 12 may include a stage 100, a bonding head 302, and a laser irradiating unit 400. The stage 100 may be configured to support a substrate 110. The bonding head 302 may be arranged apart from the upper surface of the stage 100 in the vertical direction Z. The bonding head 302 may be located to face the upper surface of the stage 100. The bonding head 302 may include a transmission unit 312, a support unit 330, and a connection unit 350.

A trench TR3 may be formed in the lower surface of the transmission unit 312. According to embodiments, the trench TR3 may have a shape extending from the lower surface of the transmission unit 312 upward in the vertical direction Z. The trench TR3 may be provided as a plurality of trenches TR3.

According to embodiments, the sidewall of the trench TR3 may be formed perpendicular to the lower surface of the transmission unit 312. In other words, the sidewall of the trench TR3 may be perpendicular to the bottom surface of the trench TR3. According to embodiments, the footprint of the trench TR3 may be greater than the footprint of the semiconductor chip 200. Accordingly, an empty space may be formed between the sidewall of the trench TR3 and the sidewall of the semiconductor chip 200. In some embodiments, a distance D1 from the sidewall of the trench TR3 to the sidewall of the semiconductor chip 200 may be 5 mm or less.

A hole H may be formed in the transmission unit 312. The hole H may be formed to penetrate the transmission unit 312 from the upper surface of the transmission unit 312 to the trench TR3. According to some example embodiments, the hole H may be or include a path through which gas passes. The support unit 330 may surround the sidewall of the transmission unit 312. The connection unit 350 may be configured to connect an elevator (not illustrated) and the support unit 330 to each other. The elevator may be configured to drive the connection unit 350 in the vertical direction Z. The laser irradiating unit 400 may be provided over or on the bonding head 302. According to example embodiments, the laser irradiating unit 400 may be provided integrally with the bonding head 302 or may be provided separately from the bonding head 302.

In a case where an empty space is formed (for example, defined) between the sidewall of the trench TR3 and the sidewall of the semiconductor chip 200, when the bonding head approaches the semiconductor chip 200 the bonding head 302, even when the semiconductor chip 200 and the bonding head 302 are misaligned partially misaligned with each other, occurrence of the edge of the trench TR3 of the bonding head 302 colliding with the upper surface of the semiconductor chip 200 may be reduced or prevented, accordingly reducing the likelihood of or preventing a crack or cracks from occurring in the semiconductor chip 200.

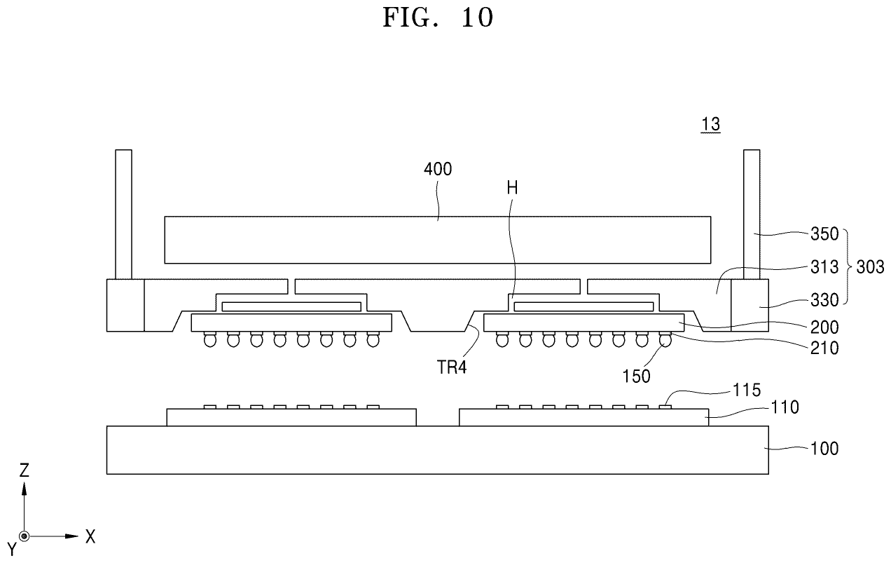

FIG. 10 is a cross-sectional view illustrating a chip bonding apparatus according to embodiments. Hereinafter, redundant descriptions of a chip bonding apparatus 13 of FIG. 10 with those of the chip bonding apparatuses 11 and 12 given above with reference to FIGS. 8 and 9 will be omitted and differences therebetween will be mainly described.

Referring to FIG. 10, the chip bonding apparatus 13 may include, for example a stage 100, a bonding head 303, and a laser irradiating unit 400. The stage 100 may be configured to support a substrate 110. The bonding head 303 may be arranged apart from the upper surface of the stage 100 in the vertical direction Z. The bonding head 303 may be located to face the upper surface of the stage 100. The bonding head 303 may include, for example, a transmission unit 313, a support unit 330, and a connection unit 350, but example embodiments are not limited thereto.

A trench TR4 may be formed in the lower surface of the transmission unit 313. According to embodiments, the trench TR4 may have a shape extending from the lower surface of the transmission unit 313 upward in the vertical direction Z. The trench TR4 may be provided as a plurality of trenches TR4.

According to some example embodiments, the footprint of the bottom surface of the trench TR4 may be greater than the footprint of the semiconductor chip 200.

The footprint of the cross-section of the trench TR4 along the X-Y plane may decrease as the level in the vertical direction Z increases. In other words, the cross-section of the trench TR4 along the X-Z plane may have a tapered shape in which the horizontal width decreases as the vertical level increases. The sidewall of the trench TR4 may form an obtuse angle with respect to the bottom surface of the trench TR4, but example embodiments are not limited thereto.

Also, the distance from the side surface of the semiconductor chip 200 to the sidewall of the trench TR4 (for example, of the transmission unit defining the trench TR4) in the horizontal direction X and Y may decrease as the footprint of the cross-section of the trench TR4 along the X-Y plane decreases as the level in the vertical direction Z increases.

A hole H may be formed in (for example, defined or at least partially defined by) the transmission unit 313. The hole H may be formed (for example, defined) to penetrate the transmission unit 313 from the upper surface of the transmission unit 313 to the trench TR4. According to some example embodiments, the hole H may be (for example, define) a path through which gas passes. The support unit 330 may surround the sidewall of the transmission unit 313. The connection unit 350 may be configured to connect an elevator (not illustrated) and the support unit 330 to each other. The elevator may be configured to drive the connection unit 350 in the vertical direction Z. The laser irradiating unit 400 may be provided over or on the bonding head 303. According to some example embodiments, the laser irradiating unit 400 may be provided integrally with the bonding head 303 or may be provided separately from the bonding head 303.

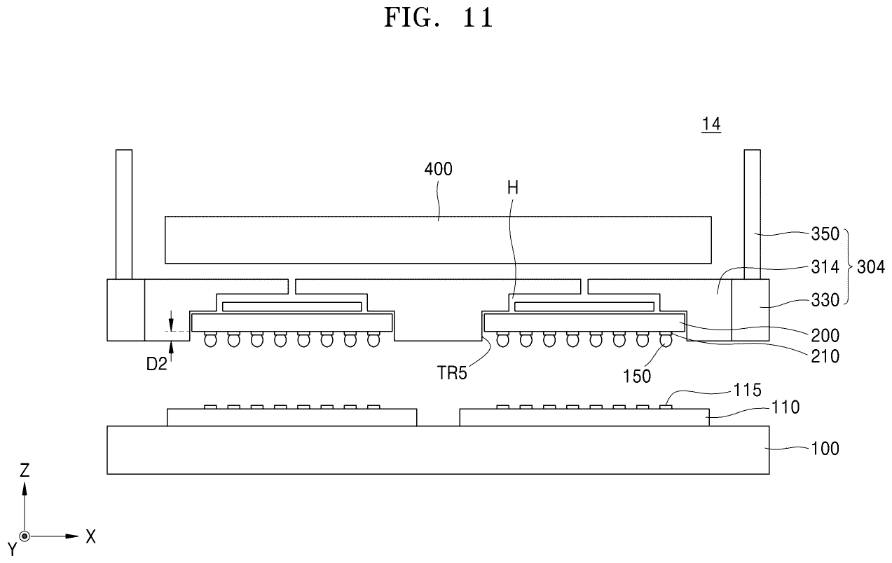

FIG. 11 is a cross-sectional view illustrating a chip bonding apparatus according to some example embodiments. Hereinafter, redundant descriptions of a chip bonding apparatus 14 of FIG. 11 with those of the chip bonding apparatus 10 given above with reference to FIGS. 2 to 7 will be omitted and differences therebetween will be mainly described.

Referring to FIG. 11, the chip bonding apparatus 14 may include a stage 100, a bonding head 304, and a laser irradiating unit 400. The stage 100 may be configured to support a substrate 110. The bonding head 304 may be arranged apart from the upper surface of the stage 100 in the vertical direction Z. The bonding head 304 may be located to face the upper surface of the stage 100. The bonding head 304 may include, for example, a transmission unit 314, a support unit 330, and a connection unit 350.

A trench TR5 may be formed in the lower surface of the transmission unit 314. According to embodiments, the trench TR5 may have a shape extending from the lower surface of the transmission unit 314 upward in the vertical direction Z. The trench TR5 may be provided as a plurality of trenches TR5. According to embodiments, the sidewall of the trench TR5 may be formed perpendicular to the lower surface of the transmission unit 314. In other words, the sidewall of the trench TR5 may be perpendicular to the bottom surface of the trench TR5.

Also, the depth of the trench TR5 in the vertical direction Z may be greater than the height of the semiconductor chip 200 in the vertical direction Z. Accordingly, when the semiconductor chip 200 is seated in the trench TR5, a certain distance D2 may be provided between the lower surface of the semiconductor chip 200 and the lower surface of the transmission unit 314. The distance D2 defined according to the depth difference between the transmission unit 314 and the semiconductor chip 200 in the vertical direction Z may reduce the occurrence of or prevent the semiconductor chip 200 and the substrate 110 from being excessively compressed.

While inventive concepts have been particularly shown and described with reference to example embodiments thereof, it will be understood that various changes in form and details may be made therein without departing from the spirit and scope of the following claims.
Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

What is claimed is:

1. A chip bonding apparatus, comprising:
a stage configured to support a plurality of substrates;
a bonding head facing an upper surface of the stage in a vertical direction and configured to hold a plurality of semiconductor chip and to transmit a laser beam; and
a laser irradiating unit configured to irradiate the laser beam toward the semiconductor chips,
wherein a plurality of trenches are at least partially defined by a lower surface of the bonding head.

2. The chip bonding apparatus of claim 1, wherein a sidewall of at least one trench of the plurality of trenches is perpendicular to a base of the at least one trench, the sidewall of the at least one trench being defined by an inner sidewall of the bonding head, the base of the at least one trench being defined by a portion of a lower surface of the bonding head.

3. The chip bonding apparatus of claim 1, wherein a horizontal width of at least one trench of the plurality of trenches decreases when moving upwards in a vertical direction, the horizontal width of the at least one trench being defined by a horizontal distance between inner sidewalls of the bonding head.

4. The chip bonding apparatus of claim 1, wherein a footprint of a base of at least one trench of the plurality trenches is greater than a footprint of a corresponding semiconductor chip, the base of the at least one trench being defined by a portion of the lower surface of the bonding head.

5. The chip bonding apparatus of claim 4, wherein a horizontal distance from a sidewall of at least one trench of the plurality of trenches to a side surface of a corresponding semiconductor chip is 5 mm or less, the sidewall of the at one trench being defined by an inner sidewall of the bonding head.

6. The chip bonding apparatus of claim 1, wherein a depth of at least one the trench of the plurality of trenches is greater than a vertical thickness of a corresponding semiconductor chip of the plurality of semiconductor chips, the depth of the at least one trench being defined by a vertical distance between portions of the lower surface of the bonding head located at different vertical levels.

7. The chip bonding apparatus of claim 1, wherein a footprint of the bonding head is greater than or equal to a sum of respective footprints of the plurality of semiconductor chips.

8. The chip bonding apparatus of claim 1, wherein the plurality of trenches comprises four trenches arranged in two rows and two columns.

9. The chip bonding apparatus of claim 1, wherein the bonding head is configured to hold at least one semiconductor ship of the plurality of semiconductor chips by vacuum compression.

10. The chip bonding apparatus of claim 1, further comprising:
a camera configured to measure an alignment state of the semiconductor chips and the substrates.

11. The chip bonding apparatus of claim 1, wherein the bonding head comprises quartz.

12. A chip bonding apparatus, comprising:
a stage configured to support a plurality of substrates;
a bonding head facing an upper surface of the stage in a vertical direction and configured to hold a plurality of semiconductor chips, transmit a laser beam, and ascend and descend in the vertical direction; and
a laser irradiating unit configured to irradiate a laser beam toward the semiconductor chips,
wherein a plurality of trenches are at least partially defined by lower surface of the bonding head,
a footprint of the bonding head is greater than or equal to a sum of respective footprints of the plurality of semiconductor chips, and
a footprint of the stage is greater than or equal to a sum of respective footprints of the plurality of substrates.

13. The chip bonding apparatus of claim 12, wherein the plurality of trenches comprises four trenches arranged in two rows and two columns.

14. The chip bonding apparatus of claim 12, further comprising:
a camera configured to measure an alignment state of the semiconductor chips and the substrates.

15. The chip bonding apparatus of claim 12, wherein a horizontal width of at least one trench of the plurality of trenches decreases when moving upwards in a vertical direction, the horizontal width of the at least one trench being defined by a distance between inner sidewalls of the bonding head.

16. The chip bonding apparatus of claim 15, wherein a footprint of a base of at least one trench of the plurality trenches is greater than a footprint of a corresponding semiconductor chip of the plurality of semiconductor chips, the base of the at least one trench being defined by a portion of the lower surface of the bonding head.

17. The chip bonding apparatus of claim 12, wherein a depth of at least one the trench of the plurality of trenches is greater than a vertical thickness of a corresponding semiconductor chip, the vertical depth of the at least one trench being defined by a vertical distance between portions of the lower surface of the bonding head located at different vertical levels.

18. A chip bonding apparatus comprising:
a stage configured to support a plurality of substrates;
a bonding head facing an upper surface of the stage in a vertical direction, the bonding head comprising a transmission unit configured to hold a plurality of semiconductor chips and transmit a laser beam, a support unit surrounding a sidewall of the transmission unit, and a connection unit connected to the support unit;
a camera configured to measure an alignment state of the semiconductor chip and the substrate; and
a laser irradiating unit configured to irradiate a laser beam toward the semiconductor chips,
wherein a plurality of trenches are at least partially defined by a lower surface of the transmission unit,
a footprint of the transmission unit is greater than or equal to a sum of respective footprints of the plurality of semiconductor chips,
a footprint of the stage is greater than or equal to a sum of respective footprints of the plurality of substrates, and
the transmission unit defines at least one holes, the at least one hole extending from an upper surface of the transmission unit to a corresponding trench of the plurality of trenches.

19. The chip bonding apparatus of claim 18, wherein a horizontal width of at least one trench of the plurality of trenches decreases when moving upwards in a vertical direction, the horizontal width of the at least one trench being defined by a distance between inner sidewalls of the transmission unit, said inner sidewalls of the transmission unit defining sidewalls of the at least one trench.

20. The chip bonding apparatus of claim 18, wherein a footprint of a base of at least one trench of the plurality trenches is greater than a footprint of a corresponding semiconductor chip, the base of the at least one trench being defined by a portion of the lower surface of the bonding head.
